(19) United States
(12) Patent Application Publication
(10) Pub. No.: US 2006/0073397 A1
(43) Pub. Date: Apr. 6, 2006

(54) Masking arrangement and method for producing integrated circuit arrangements

(76) Inventors: Johannes Freund, Munchen (DE); Michael Stetter, Munchen (DE)

Correspondence Address: BRINKS HOFER GILSON & LIONE, P.O. BOX 10395, CHICAGO, IL, 60610, US

(21) Appl. No.: 11/244,857

(22) Filed: Oct. 6, 2005

Related U.S. Application Data
(63) Continuation of application No. PCT/EP04/50524, filed on Apr. 14, 2004.

(30) Foreign Application Priority Data
Apr. 17, 2003 (DE) DE 10317893.7

(51) Int. Cl. G03C 5/00; G03F 1/00

(52) U.S. Cl. 430/5; 430/311; 430/312; 430/313

(57) ABSTRACT

A masking arrangement and method for producing integrated circuit. arrangements are described. The masking arrangement includes a substrate with lithographic patterns. The lithographic patterns are arranged in different partial regions for integrated circuits that have mutually different wiring of components as well as for test patterns. Auxiliary patterns are provided for alignment of multiple lithography planes during production of one of the circuit arrangements either with or without simultaneous production of another of the circuit arrangement. The auxiliary patterns are arranged close to corners of each of the partial regions and contain alignment or overlap marks. The auxiliary patterns and the test pattern for a particular partial region form a frame around the partial region. Filling patterns are present between the partial regions.

### PRIORITY

This application is a continuation of International Application PCT/EP2004/050524, filed Apr. 14, 2004, which claims the benefit of priority to German Patent Application DE 103 17 893.7, filed on Apr. 17, 2003, both of which are incorporated herein by reference.

### TECHNICAL FIELD

The present application relates to a masking arrangement containing a carrier substrate. More specifically, the present application relates to a carrier substrate carrying lithographic patterns that predefine patterns of an integrated circuit arrangement, the position of contact holes, or the position of doping zones.

### BACKGROUND

Masking arrangements are used in semiconductor processes to permit or block exposure of portions of a photoresist layer. As the demand for individual semiconductor devices in integrated circuits to become smaller and smaller is continually increasing, there is increasing pressure to provide lithographic techniques and masking arrangements which permit smaller feature sizes to be realized.

One such lithographic system can be found in Japanese patent application JP 11329937 A, which discloses a lithographic system in which a reticle library is utilized by two alignment systems. Measures for the arrangement of circuit arrangements on the reticules or methods for the production of small series, in particular, are not specified.

### BRIEF DESCRIPTION OF THE DRAWINGS

The following text explains in more detail a number of embodiments of the invention, using schematic drawings, in which:

FIG. 1 shows a plan view of a reticle from a set of reticles for the production of two products.

FIG. 2 shows production stages in preparation for production and in the production of integrated circuits for four different products.

FIG. 3 shows a plan view of a semiconductor wafer for producing one of the four products.

Identical or functionally identical elements are provided with the same reference symbols in the figures.

### DETAILED DESCRIPTION OF THE PREFERRED EMBODIMENTS

A masking arrangement is disclosed that contains lithographic patterns which are arranged in at least two partial regions, i.e. in two, three or more than three partial regions. Reference is made hereinafter initially only to two partial regions for the sake of better understanding. Each partial region contains patterns for an integrated circuit arrangement. By arranging auxiliary patterns for the alignment of a plurality of lithography planes, a single set of masks may be used to fabricate one of at least two different circuit arrangements in mass production without relatively large losses of semiconductor (such as silicon) area.

Two types of auxiliary patterns are present on the masking arrangement for the alignment of the lithography planes. First auxiliary patterns are used to align lithography planes during the production of a first circuit arrangement without simultaneous production of a second circuit arrangement and second auxiliary patterns are used to align lithography planes during the production of the second circuit arrangement without simultaneous production of the first circuit arrangement. Even though only two auxiliary patterns are present, they can be combined in such a way that both circuit arrangements can be produced simultaneously, for example by the selection of partial patterns.

Third auxiliary patterns may be used to align lithography planes during the simultaneous production of both circuit arrangements. This permits elimination of the combination of the first and second auxiliary patterns during the simultaneous production of both circuit arrangements as well as any measures with regard to the combination, for example programming measures.

Consequently, it is possible on account of the combination of the different types of auxiliary patterns and the masking out of partial regions that are not to be exposed or the selection of one or more partial regions to be exposed, to carry out three different fabrication methods in a different way. For example, it is possible to provide separate fabrication of the first or second circuit arrangement and simultaneous fabrication of both or all circuit arrangements.

In particular, patterns for predefining circuit arrangements for the production of the circuit arrangements of mutually different products can be arranged on the masking arrangement. At the fabrication preparation phase or the pattern production phase for the production of a small number of semiconductor wafers, by way of example, simultaneous production of all the circuit arrangements arranged on the masking arrangement with the aid of the third auxiliary patterns may be used to check the design of all the circuit arrangements. In the fabrication phase for the production of a large number of semiconductor wafers, e.g. more than 25 semiconductor wafers, by contrast, it is readily possible by means of the first and second auxiliary patterns to fabricate only one of the two circuit arrangements without using space for the other circuit arrangement on a semiconductor wafer because the other circuit arrangement can be masked out with little outlay. The first or second auxiliary patterns ensure, despite the masking out, that it is possible to carry out the alignment e.g. for a semiconductor fabrication within very close tolerances.

Each of the first and second auxiliary patterns may be arranged at one or more partial regions, but not at other locations. The third auxiliary patterns are arranged at a region formed by the one or more partial regions and preferably also within the overall region. Accordingly, there is a close spatial relationship between the auxiliary pattern and the associated region for the production of which the relevant auxiliary patterns are utilized. If the auxiliary patterns are arranged at separating regions at which a semiconductor wafer is separated into a plurality of pieces or chips, additional space requirement on the semiconductor wafer for the auxiliary patterns may be eliminated.

Between the partial regions, first auxiliary patterns may be arranged at different locations than second auxiliary patterns. This ensures a clear assignment of auxiliary patterns to a partial region. As an alternative or in addition, the third auxiliary patterns are arranged at different locations than the first auxiliary patterns and the second auxiliary patterns. In particular, the third auxiliary patterns are arranged closer to the edge of the masking arrangement than the first auxiliary patterns and the second auxiliary patterns. However, a multiple utilization of auxiliary patterns is also possible, e.g. as first auxiliary patterns and as third auxiliary patterns.

The auxiliary patterns may in each case be arranged close to corners of the partial region assigned to which they are assigned. Imaging errors are greatest in the corners, so that if the predefined tolerances are complied with in the corners, the pattern is likely to meet specifications. If, in the case of quadrangular regions, the auxiliary patterns are located in all four corners, then alignment methods can be carried out in a simple manner. If there is another auxiliary pattern in the center of a region, then the alignment can be facilitated, for example when determining the position of a plane running through all the auxiliary patterns. If the auxiliary patterns are situated at locations that are later projected on sawing lines used to separate portions of the substrate from each other, then the auxiliary patterns are situated close to the corners and outside the relevant regions.

An auxiliary pattern in each case may contain at least one alignment mark and at least one overlap mark. The alignment mark enables the alignment of the masking arrangement and of an already partly fabricated integrated circuit arrangement on a semiconductor wafer. By way of example, the alignment mark may be cruciform or contain a plurality of bars arranged parallel to one another. However, other forms of alignment marks are also possible.

The overlap mark enables checking of the offset of irradiation which is carried out with the aid of the masking arrangement. By way of example, the overlap mark contains at least one frame or at least one rectangular or square region that is filled in or left open. By means of such overlap marks, it is possible to produce so-called box-in-box structures and utilize them for compliance testing of compliance with tolerances during the irradiation of a resist. If the offset during the irradiation is too large, then the resist is removed. Afterward, a new resist layer is applied and irradiated or exposed.

The masking arrangement may additionally contain test patterns which are spatially assigned to a partial region or the overall region. By way of example, for each region there are test patterns which are used to produce ten separate circuit arrangements that in each case contain only a small number of transistors, e.g. at most about a hundred transistors. Test circuits without transistors are used as well. A suitable test circuit arrangement is an oscillator circuit, for example. The test patterns may likewise be arranged in regions that are projected onto regions for sawing lines. Multiple use of test patterns is also possible, for example of test patterns arranged between partial regions as first test patterns and as second test patterns Or of test patterns in edge regions of the masking arrangement as first test patterns and third test patterns or as second test patterns and third test patterns.

The first auxiliary patterns and the first test patterns may form one frame around a first partial region. The second auxiliary patterns and the second test patterns may form another frame around a second partial region. A third frame is formed by the third auxiliary patterns and the third test structures around the two frames. The arrangement of the auxiliary patterns and test patterns in frames makes it possible to avoid confusion of test patterns during fabrication in a simple manner.

The masking arrangement may be a mask used for 1:1 irradiation, which is to say that the patterns arranged on the mask are transferred into a resist in the same size during the exposure. Alternatively, the masking arrangement is a reticle for irradiation with demagnification, e.g. in the ratio 4:1 or 5:1. For irradiation or exposure, a wafer stepper or a wafer scanner is used both in the case of a mask and in the case of a reticle.

Lithographic patterns for integrated circuits with mutually different interconnections of components may be arranged in the partial regions. Alternatively or in addition, patterns for a plurality of circuit arrangements with mutually identical wiring of identical components are arranged in a partial region. By way of example, four control circuits for a respective controller of a hard disk in accordance with a basic version are situated in the first partial region and three control circuits for a respective controller of a version with extended functions, e.g. with an integrated volatile memory, are situated in the second partial region. This permits simultaneous exposure of a plurality of circuit arrangements of the same type during the later fabrication of circuits of a selected product.

Filling patterns may also exist. More specifically, first filling patterns and second filling patterns may be present between the two partial regions. The first filling patterns may surround or enclose the first partial region, the first auxiliary patterns and the first test patterns, but not the second partial region, the second filling patterns, the second test patterns and the second auxiliary patterns. The second filling patterns may surround or enclose the second partial region, the second auxiliary patterns and the second test patterns. However, the first partial region, the first filling patterns, the first auxiliary patterns and the first test patterns are not surrounded by the second filling patterns. The filling structures are, for example bars or squares at uniform distances from one another. In the selection of the circuit arrangements of a specific product on the masking arrangement, the other patterns can be masked out distinctly only with an increased outlay on apparatus. If an increased outlay is not expended, then there are intersection regions in which, however, the filling patterns can be arranged in a simple manner, so that said intersection regions are less disturbing. The filling regions are also suitable, particularly in advanced CMOS technologies (complementary metal oxide semiconductor) with minimum feature sizes of less than 0.35 or 0.25 micrometer, for ensuring homogeneity of the structures on a semiconductor wafer that enables the production process. In technologies with less stringent homogeneity requirements, a homogeneous blackening or a radiation-transmissive region may be arranged in place of the filling patterns.

An electronic data record is used that contains data that defines the position of the patterns of the masking arrangement. The electronic data record contains a plurality of data fields which, for their part, are combined to form groups, for example a group for the first partial region, a group for the second partial region and a group for the overall region. By way of example, the data are contained in binary form in the data record.

Furthermore, a program is used to define the position of patterns of the masking arrangement. The program contains a function for combining the first partial region, the first auxiliary patterns and preferably also the first test patterns to form a first block and for combining the second partial region, the second auxiliary patterns and preferably also the second test patterns to form another block. The program may make it possible to combine these two blocks together with the third auxiliary patterns and the third test patterns to form a third block, which is also referred to as overall block for the masking arrangement.

A method for producing integrated circuit arrangements using the masking arrangement is also described. The method includes fabricating a masking arrangement containing at least two partial regions with patterns for integrated circuit arrangements. The circuit arrangements differ from test circuit arrangements as the circuit arrangements are utilized later by the users of a product, whereas the test circuits are unimportant to the user of the product. One partial region is selected for the irradiation and exclusion of the other partial region from the irradiation, examples of suitable measures being that the masking arrangement is cut up or unused partial regions are masked out. Irradiation of a resist-coated substrate, e.g. a fabrication semiconductor wafer, and transfer of the pattern of the selected partial region into the resist layer without transfer of the pattern of the other partial region into the resist layer is performed one or more times. In this case, the selected partial region is preferably projected into the resist layer in such a way that the semiconductor wafer is densely covered with the selected partial regions. The selected partial regions then lie edge to edge on the semiconductor wafer.

This ensures that the production costs for the masking arrangement are low because patterns for a plurality of mutually different circuit arrangements can be arranged on one masking arrangement. On the other hand, there is only a slight increase in the costs during the production of a selected circuit arrangement on account of multiple exposures.

Once the masking arrangement has been removed again from an exposure arrangement and stored for several weeks, the other partial region is selected for an irradiation. The partial region that has already been utilized for production and, if appropriate, other partial regions as well are excluded from the irradiation or exposure. Afterward, a further resist-coated fabrication semiconductor wafer is irradiated one or more times, the pattern of the selected partial region being transferred into the resist layer without patterns from other partial regions being transferred into the resist layer. The other product can thus also be fabricated with low fabrication costs.

The masking arrangement may be in each case introduced into the exposure installation into which the fabrication semiconductor substrate is also introduced. This means that the masking arrangement still carries patterns for all the partial regions. After the irradiation, the masking arrangement and the fabrication semiconductor substrate are removed from the irradiation device. The masking arrangement is stored for the next use. By contrast, the fabrication semiconductor substrate is processed further independently of the storage of the masking arrangement. Thus, by way of example, the number of masking arrangements to be stored is reduced in comparison with a separation of the masking arrangement into different partial regions or for the selection of a partial region by means of a different measure with the same effect.

Alternatively, the masking arrangement and a resist-coated fabrication preparation semiconductor substrate may be introduced into an irradiation device, and the fabrication preparation semiconductor substrate irradiated and the patterns of both partial regions transferred into the resist layer of the fabrication preparation semiconductor substrate.

In the fabrication preparation phase, on one fabrication preparation semiconductor substrate, by way of example, the circuit arrangements for products A are sawn out, the circuit arrangements for products B in other partial regions being destroyed. On another fabrication preparation semiconductor substrate, by contrast, the products B are sawn out, the products A being destroyed. Given the small number of semiconductor wafers to be fabricated in preparation for production, such a procedure is acceptable particularly in comparison with the reduction of the costs for producing the masking arrangement.

In the fabrication phase, by contrast, only one partial region of the masking arrangement is irradiated, resulting in the production of adjacent irradiation zones with circuit arrangements aligned in a sawing grid on the semiconductor wafer. Moreover, the entire wafer area can be densely covered with the selected partial regions even though partial regions for different products are arranged within the same set of masks or set of reticles.

In the case of relatively small series, in particular, the masking arrangement and the method are particularly suitable for fabrication with a low fabrication outlay, for example for products for the production of which fewer than a thousand wafers are processed.

A frame is provided for each productive partial region. The frame contains all the optical structures or electronic structures for the control of fabrication or for the quality control of the fabricated circuits. Moreover, filling structures are provided between the partial regions, if appropriate, which facilitate or enable the production.

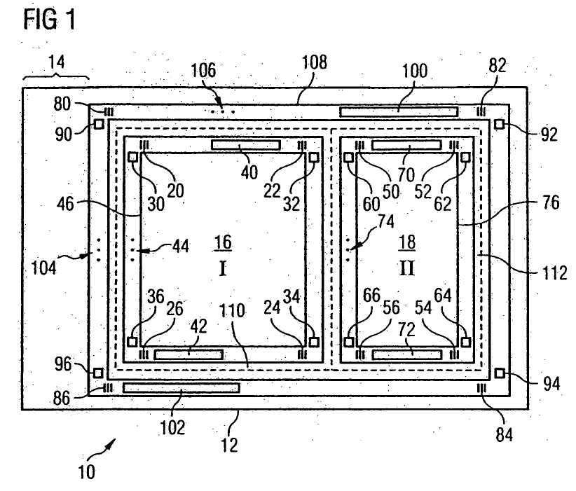

FIG. 1 shows a plan view of a reticle 10 from a set of reticles for the production of two products I and II. In addition to the reticle 10, the set of reticles contains for example 30 or more reticles. Each reticle in the set of reticles is arranged like the reticle 10 on a reticle substrate 12, for example on a glass substrate. A left-hand edge region 14 of each reticle serves for housing and contains no patterns. Like the reticle 10, each reticle in the set of reticles contains two partial regions 16, 18 in which patterns for producing the useful circuit arrangements are arranged. The partial region 16 lies in a central part of the reticle 10 and has an almost square form. Patterns for producing the product I are arranged in the partial region 16. The partial region 18 lies in the right-hand part of the reticle 10 and has a rectangular form. Patterns for producing the product II lie in the partial region 18.

The partial region 16 is surrounded by four alignment marks 20 to 26, by four overlap marks 30 to 36, by two test structures 40, 42 and also by further auxiliary patterns 44, which all together form an almost square frame 46 completely surrounding the partial region 16. The alignment marks 20 to 26 and the overlap marks 30 to 36 are in each case situated at the corners of the partial region 16. The alignment marks 20 to 26 contain for example in each case three or five bars which are arranged parallel to one another and run in the vertical direction. The overlap marks 30 to 36 in each case contain a square frame. The dimensions of the alignment marks 20 to 26 and of the overlap marks 30 to 36 are in each case less than 20 μm, by way of example. The test structure 40 lies between the alignment marks 20 and 22 in the right-hand part of the upper frame web of the frame 46. The test structure 42 lies between the alignment marks 24 and 26 in the left-hand part of the lower frame web of the frame 46.

The partial region 18 is surrounded by alignment marks 50 to 56, by overlap marks 60 to 66, by test structures 70, 72 and by further auxiliary structures 74, which all together form a rectangular frame 76. The alignment marks 50 to 56 and the overlap marks 60 to 66 are in each case arranged in the corners of the frame 76. The alignment marks 50 to 56 in each case contain three or, in another exemplary embodiment, five vertical bars. The overlap marks 60 to 66 are rectangular frames in each case. The test structure 70 lies between the alignment marks 50 and 52. The test structure 72 lies between the alignment marks 54 and 56 on the lower frame web of the frame 76. The sizes of the structures of the frame 76 are identical to the size of the structures of the frame 46.

The two frames 46 and 76 are surrounded by four alignment marks 80 to 86, by four overlap marks 90 to 96, by two test structures 100, 102 and also by further auxiliary structures 104, 106 which all together form a superframe 108. The alignment marks 80 to 86 and the overlap marks 90 to 96 are arranged in the corners of the superframe 108 and have the same construction as the alignment marks 20 to 26 and 50 to 56 and as the overlap marks 30 to 36 and 60 to 66. The test structure 100 is arranged between the alignment marks 80 and 82 in the upper frame web of the superframe 108. The test structure 102 is arranged between the alignment marks 84 and 86 in the lower frame web of the superframe 108.

The arrangement of the alignment marks 20 to 26, 50 to 56, 80 to 86 and of the overlap marks 30 to 36, 60 to 66 and 90 to 96 in the respective frame 46, 76 and 108 is thus similar in comparison with the respective other frames. In other reticles in the set of reticles, alignment marks and overlap marks are also situated in the vicinity of the corners of the respective frames, but if appropriate with an offset with respect to the overlap marks explained with reference to FIG. 1.

The reticle 10 also contains, in the frames 46, 76 and in the superframe 108, other marks as well, for example marks for the horizontal alignment, which are constructed like the alignment marks 20 to 26, but whose bars lie in the horizontal direction.

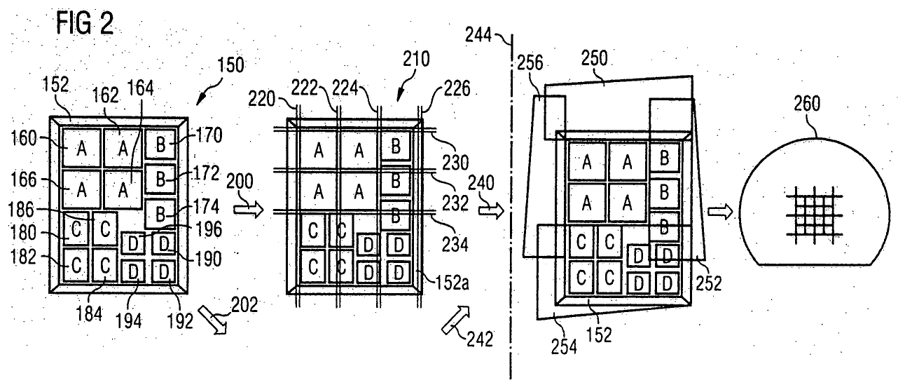

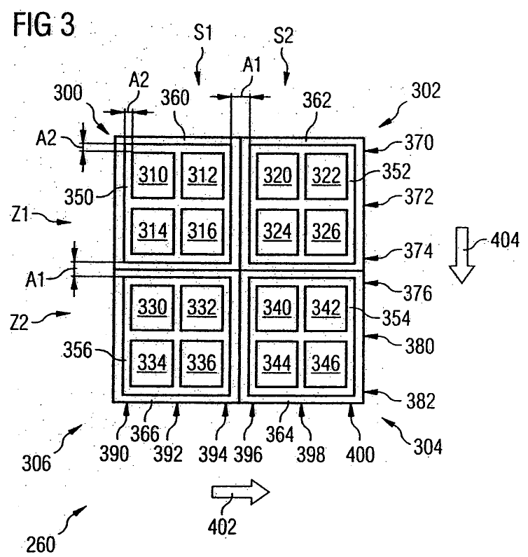

As explained below with reference to FIGS. 2 and 3 for a reticle from a different set of reticles, three different production methods can be carried out with the set of reticles that also includes the reticle 10, namely: 1) production of both products I and II using the superframe 108 and without coverage of partial regions 16 and 18, respectively, 2) production only of the product I using the frame 46 and with simultaneous coverage of the partial region 18, the frame 76 and the superframe 108, and 3) sole production of the product II using the frame 76 and with simultaneous coverage of the partial region 16, the frame 46 and the frame 106.

The region between the frame 46, 76 and 108 is blackened, by way of example. However, there are also exemplary embodiments without blackening.

Thus, in another exemplary embodiment, the reticle 10 additionally carries filling structures arranged in two filling frames 110, 112. The filling frame 110 adjoins the frame 46. The filling frame 112 adjoins the frame 76. Both filling frames 110 and 112 lie within the superframe 108. The function of the filling frames 110 and 112 is likewise explained in more detail below with reference to FIGS. 2 and 3.

In another exemplary embodiment, there is a distance between adjacent sides of the filling frames 110 and 112. The distance is for example greater than 10 micrometers or greater than 100 micrometers.

FIG. 2 shows production stages in preparation for production and for the production of integrated circuits for four different products A to D. A reticle manufacturer is commissioned to produce a set of reticles containing a reticle 150. The reticle 150 contains, surrounded by a superframe 152 similar to the superframe 108.

Four subregions 160 to 166 for four products A are disposed in the top left corner of the superframe 108. The partial regions 160 to 166 are arranged in two rows and two columns so as to form a square partial region for the product A.

In the upper and central parts of the right-hand edge region of the superframe 108, for three products B, three square subregions 170 to 174 are arranged in a column. In the bottom left corner of the superframe 108, for four products C, four subregions 180 to 186 likewise are arranged in two rows and two columns, and in the bottom right corner, for four products D, four subregions 190 to 196 likewise are arranged in two rows and two columns.

The subregions 160 to 166, 170 to 174, 180 to 186 and 190 to 196 for product A, B, C and D, respectively, in each case form a partial region which is surrounded by a dedicated frame which contains alignment marks, overlap marks and test structures. The superframe 152 also contains alignment marks, overlap marks and test structures. By contrast, individual subregions 160 to 196 are not surrounded by a frame with auxiliary structures that surrounds only them.

On the basis of the set of reticles comprising the reticle 150, four test wafers are produced, as shown by arrows 200 and 202. In the case of the arrow 200, a test wafer 210 is produced for test circuits of the product A. Alignment patterns, overlap patterns and test structures are arranged in a superframe 152a produced on the test wafer 210; they have been produced with the aid of the alignment patterns, overlap patterns and test structures arranged in the superframe 152. Vertical sawing lines 220 to 226 and horizontal sawing lines 230, 232 and 234 serve for cutting out chips for the product A. Many of the other chips for the products B, C and D are sawn apart during sawing since they do not necessarily lie in the grid of the sawing lines 220 to 234.

As indicated by arrows 240 and 242, tests are then carried out for checking the design for the test circuits of the products A to D. It is assumed in the exemplary embodiment that these tests proceed without any errors. A vertical broken line 244 illustrates the conclusion of the production preparation or fabrication preparation. The set of reticles that also includes the reticle 150 is kept in a reticle library until the product A, by way of example, is to be produced following receipt of a customer's order.

Whereas no subregions 160 to 196 were masked out in the production of the test wafer 210, for producing the product A an exposure device with four diaphragms 250 to 256 is used, with the aid of which only the subregions 160 to 166, i.e. the partial region for the product A, and also the frame that surrounds only this partial region, and if appropriate the associated filling frame, are transferred to a production wafer 260. The diaphragm 250 covers the upper frame web of the superframe 152. The right-hand diaphragm 252 covers the subregions 170 to 174 for the product B. The lower diaphragm 254 covers the subregions 190 to 196 for the product C and for the product D. The left-hand diaphragm 256 covers the left-hand frame web of the superframe 152. The exposure structures produced on the production wafer 260 are explained in more detail below with reference to FIG. 3.

FIG. 3 shows a plan view of a detail from the production wafer 260 after the end of the lithography method carried out using the reticle 150. Four partial regions 300 to 306 that are in each case produced by means of a partial exposure are arranged in matrix form in two columns S1, S2 and two rows Z1, Z2, each region 300 to 306, for its part, in each case containing four subregions 310 to 316, 320 to 326, 330 to 336 and 340 to 346, respectively. By way of example, the four subregions 310 to 316 were produced with the aid of the subregions 160, 162, 164 and 166, in particular the subregion 310 with the subregion 160 and the subregion 312 with the subregion 162.

The partial regions 300 to 306 are in each case surrounded by a frame 350 to 356. The frames 350 to 356 in each case contain alignment marks and overlap marks in the corners. Test structures are arranged in the edge regions of the frames 350 to 356. Situated between the subregions of a partial region 300 to 306, e.g. between the subregions 310, 312, 314 and 316, are vertical or horizontal strips in which sawing lines will later run. In one exemplary embodiment, alignment marks, overlap marks and test structures are likewise arranged within the strips.

Moreover, each frame 350 to 356 is surrounded by filling frames 360 to 366 in which recessed and projecting rectangular regions alternate. The filling frames of adjacent partial regions 300 to 306 adjoin one another. A distance A1 specifies twice the width of the region of a filling frame exposed with filling structures. In the exemplary embodiment, the distance A1 is 900 μm (micrometers). In other exemplary embodiments, the magnitude of the distance A1 lies e.g. between 100 μm and 1 mm (millimeter). The webs of the frames 350 to 356 in each case have a width of e.g. 90 μm, see distance A2. The position of horizontal sawing lines 370 to 382 and of vertical sawing lines 390 to 400 is illustrated by arrows in FIG. 3. Since all the circuit arrangements on the production wafer 260 lie in the grid of sawing lines, separation is effected without destroying circuit arrangements.

The structure shown in FIG. 3 is continued in a row direction 402 indicated by an arrow and in a column direction 404 indicated by an arrow. Superframes corresponding to the superframe 152 are not arranged on the production wafer 260.

In other exemplary embodiments, more than four partial regions lie within an exposure region for the production of a product. Moreover, other exemplary embodiments do not use filling frames 360 to 366.

In another exemplary embodiment, the superframe 108 is not present. Instead, the alignment marks and: the test structures of both frames 46 and 76 are used during the simultaneous production of both products I and II. For alignment purposes, only the alignment marks 20, 52, 54 and 26 are used, i.e. the alignment marks arranged in the corners of an overall region comprising the two partial regions. By contrast, the alignment marks 22, 50, 56 and 24 are not utilized for the alignment during simultaneous production.

In a further exemplary embodiment, filling patterns are arranged on the reticle only at two adjoining sides of each partial region and not at the other two sides. Exposure of adjacent partial regions gives rise to a filling structure frame on the wafer, however. In this exemplary embodiment, the distance A1 corresponds simply to the width of a filling pattern web. In particular, filling structures are not necessary at the mask or reticle edge since masking out is effected there e.g. by means of a holder of the reticle that is situated together with the reticle at the focal point of the exposure installation. Only additionally required diaphragms are situated outside the focused plane and are not sharply imaged. This is acceptable, however, on account of the filling patterns or a suitable distance.

In both cases of the arrangement of filling patterns, filling structures produced by means of different exposures can be arranged both in overlapping fashion and in non-overlapping fashion on the wafer.

It is therefore intended that the foregoing detailed description be regarded as illustrative rather than limiting, and that it be understood that it is the following claims, including all equivalents, that are intended to define the spirit and scope of this invention. Nor is anything in the foregoing description intended to disavow scope of the invention as claimed or any equivalents thereof.

1. A masking arrangement for producing integrated circuit arrangements, the masking arrangement comprising:
a carrier substrate;
first and second lithographic patterns carried by the carrier substrate arranged in first and second partial regions, respectively, the first lithographic patterns arranged in the first partial region for a first integrated circuit arrangement, the second lithographic patterns arranged in the second partial region for a second integrated circuit arrangement, the first and second integrated circuit arrangements having mutually different wiring of components;
first auxiliary patterns for alignment of a plurality of lithography planes during production of a first of the circuit arrangements without simultaneous production of a second of the circuit arrangements; and
second auxiliary patterns for alignment of a plurality of lithography planes during the production of the second circuit arrangement without simultaneous production of the first circuit arrangement.

2. The masking arrangement as claimed in claim 1, further comprising third auxiliary patterns for alignment of a plurality of lithography planes during simultaneous production of the first and second circuit arrangements, the third auxiliary patterns containing a combination of the first and second auxiliary patterns or being present in addition to the first and second auxiliary patterns.

3. The masking arrangement as claimed in claim 2, wherein at least one of:
the first auxiliary patterns are arranged at the first partial region, the second auxiliary patterns are arranged at the second partial region, and the third auxiliary patterns are arranged at an overall region formed by the first and second partial regions;
between the first and second partial regions, the first auxiliary patterns are arranged at different locations than second auxiliary patterns; or
the third auxiliary patterns are arranged at different locations than the first auxiliary patterns and the second auxiliary patterns.

4. The masking arrangement as claimed in claim 2, wherein at least one of:
the first auxiliary patterns are arranged close to corners of the first partial region;
the second auxiliary patterns are arranged close to corners of the second partial region; or
third auxiliary patterns are arranged close to corners of an overall region formed by the first and second partial regions.

5. The masking arrangement as claimed in claim 2, wherein at least one of:
at least one of the first, second or third auxiliary patterns contains an alignment mark which enables alignment of the masking arrangement and of the respective integrated circuit arrangement; or
at least one of the first, second or third auxiliary patterns contains an overlap mark which enables checking of offset of an irradiation performed with aid of the masking arrangement.

6. The masking arrangement as claimed in of claim 2, further comprising at least one of:
a first test pattern for the production of a first test circuit arrangement at the same time as the first circuit arrangement;
a second test pattern for the production of a second test circuit arrangement at the same time as the second circuit arrangement; or
a third test pattern for the production of a third test circuit arrangement at the same time as the first and second circuit arrangements.

7. The masking arrangement as claimed in claim 6, wherein at least one of:
the first auxiliary patterns and the first test pattern form a first frame around the first partial region;
the second auxiliary patterns and the second test pattern form a second frame around the second partial region; or
the third auxiliary patterns and the third test pattern form a third frame around the first and second frames.

8. The masking arrangement as claimed in claim 1, wherein the masking arrangement comprises a mask for 1:1 irradiation or a reticle for irradiation with demagnification of the first and second lithographic patterns.

9. The masking arrangement as claimed in claim 1, wherein the first lithographic patterns with mutually identical wiring of components are arranged in the first and second partial regions.

10. The masking arrangement as claimed in claim 2, further comprising filling patterns between the first and second partial regions.

11. The masking arrangement as claimed in claim 2, wherein the third auxiliary patterns are arranged closer to an edge of the masking arrangement than the first auxiliary patterns and the second auxiliary patterns.

12. The masking arrangement as claimed in claim 4, wherein at least one of: at least one first auxiliary pattern is arranged close to each corner of the first partial region, at least second first auxiliary pattern is arranged close to each corner of the second partial region, or at least one third auxiliary pattern is arranged close to each corner of the overall region.

13. The masking arrangement as claimed in claim 4, wherein at least one of:
the alignment mark comprises a cross or a plurality of rectilinear structures arranged parallel to one another; or
the overlap mark comprises a frame or a rectangular or square area.

14. The masking arrangement as claimed in claim 10, wherein the filling patterns comprise a first filling pattern frame surrounding the first partial region and the first auxiliary patterns, and a second filling pattern frame surrounding the second partial region and the second auxiliary patterns.

15. An electronic data record comprising data that defines a position of patterns of a masking arrangement that comprises:
a carrier substrate;
first and second lithographic patterns carried by the carrier substrate arranged in first and second partial regions, respectively, the first lithographic patterns arranged in the first partial region for a first integrated circuit arrangement, the second lithographic patterns arranged in the second partial region for a second integrated circuit arrangement, the first and second integrated circuit arrangements having mutually different wiring of components;
first auxiliary patterns for alignment of a plurality of lithography planes during production of a first of the circuit arrangements without simultaneous production of a second of the circuit arrangements; and
second auxiliary patterns for alignment of a plurality of lithography planes during the production of the second circuit arrangement without simultaneous production of the first circuit arrangement.

16. A program for defining a position of patterns of a masking arrangement that comprises:
a carrier substrate;
first and second lithographic patterns carried by the carrier substrate arranged in first and second partial regions, respectively, the first lithographic patterns arranged in the first partial region for a first integrated circuit arrangement the second lithographic patterns arranged in the second partial region for a second integrated circuit arrangement, the first and second integrated circuit arrangements having mutually different wiring of components;
first auxiliary patterns for alignment of a plurality of lithography planes during production of a first of the circuit arrangements without simultaneous production of a second of the circuit arrangements; and
second auxiliary patterns for alignment of a plurality of lithography planes during the production of the second circuit arrangement without simultaneous production of the first circuit arrangement,
wherein the program functions for combining the first partial region and auxiliary patterns associated with the first partial region to form a first block and for combining the second partial region and auxiliary patterns associated with the second partial region to form a second block.

17. A method for producing integrated circuit arrangements comprising the following steps to be performed without restriction by the order specified:
fabricating a masking arrangement containing a first and a second partial region with lithographic patterns for a first and second integrated circuit arrangement, respectively, the first and second integrated circuit arrangements having mutually different wiring of components, the first and second integrated circuit arrangements differing from test circuits by the first and second integrated circuit arrangements being usable by users of a product having the first and second integrated circuit arrangements whereas the test circuits are not usable by the user of the product,
selecting one of the first and second partial regions for irradiation and excluding the other of the first and second partial regions from the irradiation; and
irradiating a resist-coated fabrication substrate and transferring the pattern of the one partial region into a first resist layer without transferring the pattern of the other partial region into the first resist layer.

18. The method as claimed in claim 17, further comprising:
selecting the other partial region for irradiation and excluding the one partial region from the irradiation and
irradiating a second resist-coated fabrication substrate and transferring the pattern of the other partial region into a second resist layer without transferring the pattern of the one partial region into the second resist layer.

19. The method as claimed in claim 17, further comprising introducing the masking arrangement into an irradiation device and introducing the substrate into the irradiation device prior to irradiating the substrate.

20. The method as claimed in claim 15, further comprising prior to the introduction or the irradiation of the fabrication substrate:
introducing the masking arrangement and a resist-coated fabrication preparation substrate into the irradiation device,
irradiating the fabrication preparation substrate and transferring the patterns of the first and second partial regions into a resist layer of the fabrication preparation substrate.
